(19) United States
(12) Patent Application Publication
(10) Pub. No.: US 2012/0100660 A1
(43) Pub. Date: Apr. 26, 2012

(54) METHOD FOR PREPARATION OF METAL CHALCOGENIDE SOLAR CELLS ON COMPLEXLY SHAPED SURFACES

(76) Inventors: Kevin V. Hagedorn, Northville, MI (US); Wei Guo, Canton, MI (US); Bing Liu, Ann Arbor, MI (US)

(21) Appl. No.: 13/053,441

(22) Filed: Mar. 22, 2011

Related U.S. Application Data
(63) Continuation-in-part of application No. 12/910,929, filed on Oct. 25, 2010.

(51) Int. Cl. H01L 31/0352

(52) U.S. Cl. 438/63; 257/E31.032; 977/773

(57) ABSTRACT

Methods for fabricating a photovoltaic device on complexly shaped fabricated objects, such as car bodies are disclosed. Preferably the photovoltaic device includes absorber layers comprising Copper, Indium, Gallium, Selenide (CIGS) or Copper, Zinc, Tin, Sulfide (CZTS). The method includes the following steps: a colloidal suspension of metal surface-charged nanoparticles is formed; electrophoretic deposition is used to deposit the nanopartieles in a metal thin film onto a complexly shaped surface of the substrate; the metal thin film is heated in the presence of a chalcogen source to convert the metal thin film into a metal chalcogenide thin film layer; a buffer layer is formed on the metal chalcogenide thin film layer using a chemical bath deposition; an intrinsic zinc oxide insulating layer is formed adjacent to a side of the buffer layer, opposite the metal chalcogenide thin film layer, by chemical vapor deposition; and finally, a transparent conducting oxide is formed adjacent to a side of the intrinsic zinc oxide, opposite the buffer layer, by chemical vapor deposition.

### RELATED APPLICATIONS

The present application claims the benefit of U.S. application Ser. No. 12/910,929, filed on Oct. 25, 2010 as a continuation-in-part application of that application. U.S. application Ser. No. 12/910,929, filed on Oct. 25, 2010, is hereby incorporated by reference in its entirety.

### STATEMENT REGARDING FEDERALLY SPONSORED RESEARCH

NONE.

### TECHNICAL FIELD

The present invention relates to fabrication of a photovoltaic absorber layer and a photovoltaic device incorporating the layer wherein the photovoltaic absorber layer is fabricated by electrophoretic deposition of nanoparticles of an absorptive material on complexly shaped surfaces of fabricated objects.

### BACKGROUND

Compound semiconductors based on an absorber layer of chalcopyrite or kesterite are some of the most promising materials for solar cells. The chalcopyrite material Cu(In,Ga)Se₂ (CIGS), is a direct bandgap semiconductor that has demonstrated solar-to-electrical energy conversion efficiencies in excess of 20%. Remarkably, high efficiencies have been achieved using multi-crystalline materials and with stoichiometric compositions that vary by 5-10%; virtually all other semiconductor materials need to be single crystalline and defect-free to show any significant energy conversion efficiency. Metal chalcogens such as CIGS perform as p-type solar absorbers and have the best performance when the atomic ratio between these group IB:IIIA:VIA elements, e.g., Cu:(In+Ga):Se is strictly controlled near 25%:25%:50% with allowable deviations towards Cu-deficient and Se-rich by percents of plus or minus 15%. This predetermined ratio is known and is adhered to in the design of these solar absorbers. The high tolerance of this CIGS material to varying material composition and defects is being leveraged to explore new low-cost methods for making large-area, tow-cost photovoltaics. In particular, solution-based processes that involve spraying, printing or electrodeposition are currently being investigated, and some of these processes have achieved efficiencies above 10%. The realization of high-efficiency solar panels that can be deposited from solution would result in devices that can generate energy that are cost-competitive with fossil fuels. Alternatively, kesterite materials such as Cu₂ZnSn(S,Se)₄ (CZTS) are a related semiconductor material that replaces indium and gallium with zinc and tin. These devices are attractive because they do not require the rare earth element indium. Kesterite materials have demonstrated efficiencies of 9.6% and may be an alternative to CIGS if indium is limiting. In CZTS cells the atomic ratio between these group IB:(IIB+IVA):VIA elements, e.g. Cu:(Zn+Sn):(S+Se) is also strictly controlled near the predetermined ratio of 25%:25%:50%, with allowable deviations also towards slightly Cu-deficient and (S+Se)-rich by a few percents of plus or minus 15%.

Though the cost of solar panels is decreasing, installation costs still account for half of the cost of solar energy; this can be addressed by bundling solar cells with other consumer goods. In current manufacturing schemes for silicon-based photovoltaics, the processed and purified silicon compromises only 10% of the final cost of the cell, and manufacturing costs account for another 40%. The remainder of the cost is associated with module installation and other fixed costs such as inverter installation and connecting the cells to the grid. As the cost of solar cell modules continues to decrease, installation costs are poised to become greater than the module costs. Bundling solar cells with other consumer goods so that the energy generated by the solar cells can directly power the device rather than requiring that the cells first be connected to the electrical grid can offset the installation costs. One example could be the deposition of a photovoltaic paint on a car body, which would provide power to drive the car or charge the battery. Another example could be photovoltaic siding or roof tiles, the energy generated from which could be used for heating or cooling. For these applications, a method for depositing a conformal coating of the photovoltaic material on curved or complexly shaped surfaces is necessary. By complexly shaped surfaces in the present specification and claims it is meant that the object to be coated has a plurality of surfaces that are not all in the same plane. In typical solar panel construction the panels are flat, planar surfaces. In the present invention a complexly shaped surface is a non-planar surface meaning that the surface topography or surfaces of the object to be coated exist in at least two different planes, although a surface or a portion of it can be planar itself. Such shapes include, for example only and without limitation, cylinders, concave surfaces, convex surfaces, curvilinear surfaces, two surfaces that contact each other in a non-planar fashion and mixtures of these shapes.

One application that requires the deposition of a CIGS layer onto a curved surface is the manufacture of cylindrical solar cells. See Buller and Beck; “Monolithic Integration of Cylindrical Solar Cells” U.S. Pat. No. 7,235,736. Two strategies were previously developed to deposit CIGS on these cylindrical surfaces, but each has drawbacks. The first method is to deposit the CIGS solar cells on a flexible substrate using standard techniques, such as physical vapor deposition (PVD), and then wrap the solar cell film around a tube which is then inserted inside a larger glass tube. The disadvantage of this wrapping approach is the shear stress which occurs in the film. CIGS is a ceramic material that is prone to cracking; the wrapping process can stress the film, reducing efficiency. Another method that has been proposed is electrochemical deposition. However, though electrochemical deposition can be used to deposit a conformal absorber layer, deposition of all of the necessary elements from a single electrochemical deposition bath is difficult because of the large difference in deposition potentials of copper, indium, gallium, and selenium. While theoretically possible, no uniform deposition of CIGS from a single bath has been demonstrated. It is possible to electroplate each element in a series of four baths and subsequently fuse the layers in an annealing step, but a simpler method requiring fewer baths and no annealing step would be preferable to reduce equipment costs and the thermal budget.

With the exception of electrochemical deposition, all of the other methods that have been developed for depositing CIGS are line-of-sight techniques, which make them incompatible with deposition on complexly shaped surfaces. Methods based on physical vapor deposition, spray pyrolysis, or those that spray or sputter the source material from a nozzle or target cannot deposit a uniform coating on complexly shaped surfaces due to shadowing effects. In photovoltaic devices uniformity in the composition and thickness of the absorber material are critical to obtaining high efficiency devices.

Typical photovoltaic laminates comprise, in order: a substrate that acts as or is coated with a back electrode material; a photovoltaic CIGS or CZTS absorber layer; a window layer typically of CdS; a transparent electrode material, typically of intrinsic ZnO (i-ZnO) and/or aluminum doped ZnO (Al—ZnO) and a top electrical contact of a metal such as nickel, aluminum or other conductive metal. The laminate also often includes a final outer protective layer of anti-reflective material. Deposition of the i-ZnO intrinsic layer and Al—ZnO conductive layer are likewise typically deposited using line-of-sight techniques. Conductive zinc oxide has been prepared using a number of techniques, including magnetron sputtering, chemical vapor deposition, pulsed laser ablation, evaporation, spray pyrolysis, sol-gel preparation, and electrochemical deposition. Industrial preparation of Al—ZnO films has been limited almost exclusively to magnetron sputtering, as this method creates the most conductive thin films. However, this technique cannot be used to create a conformal coating because it is directional and not conformal. The only techniques that can be used to prepare a conformal coating are electrochemical deposition, sol-gel and chemical vapor deposition.

One method of forming a thin film, electrophoretic deposition (EPD), is a broadly acknowledged non-vacuum coating method employed in automotive, appliance, and general organic industries. During the process of EPD, surface-charged particles suspended in a liquid medium will migrate under the influence of an external electric field and be rapidly deposited onto an electrically conductive or semi-conductive surface having the opposite charge. High density films of metals, ceramics, polymers, semiconductors, or carbon have been deposited as described in the prior art such as in “The mechanism of electrophoretic deposition” by Brown and Salt in J. Appl. Chem., 15, 40 (1965), and in U.S. Pat. Nos. 3,879,276; 4,204,933; 4,225,408; and 4,482,447. The above described prior art all require delicate procedures for making the nanopartiele suspension in solution, which involves chemical synthesis such as a metathetical reaction or a reduction reaction to form the nanoparticles, and the described EPD processes typically required assistance of specific acids or bases, stabilizers, and/or binding agents. In addition, some of the described processes required use of post-deposition high temperature treatments at 300 to 800° C. to form the final film as described in U.S. Pat. Nos. 4,204,933 and 4,225,408. These delicate procedures disclose vulnerability and complexity in EPD process control and increase the processing cost accordingly. In addition, the use of chemical reactants and assisting additives will inevitably result in waste of raw materials and introduce chemical contaminations into the suspension and onto the deposited film. Thus, an EPD process has not found use in the highly desired production of large-scale solar panels.

### SUMMARY OF THE INVENTION

The present invention provides techniques for fabricating a photovoltaic device that has a chalcopyrite absorber layer, such as copper indium gallium selenide/sulfide (CIGS) or Copper Zinc Tin Sulfide (CZTS), on a complexly shaped surface of a fabricated object.

In certain embodiments the method includes the following steps: providing a stable colloidal suspension of metal surface-charged nanoparticles in a non-aqueous solvent, the nanoparticles comprising elements either from Groups IB, IIIA and optionally Group VIA or from Groups IB, IIB and/or IVA and optionally VIA; electrophoretic deposition of the nanoparticle suspension onto the complexly shaped surfaces of objects in a metal thin film is accomplished by electrophoretic deposition (EPD) by applying a voltage of 50-5000 volts (V) between the surface to be coated, which is at least semi-electrically conductive or has an at least semi-electrically conductive coating on it and a shaped counter electrode; finally, the metal thin film is converted into a metal chalcogenide film by heating the nanoparticle metal thin film in the presence of a chalcogen. A CdS buffer layer, an i-ZnO insulating layer, and an Al—ZnO transparent conducting oxide are then deposited over the metal chalcogenide thin film, with each being done using a chemical deposition technique. A chemical bath deposition is used to deposit the CdS buffer layer from Cd²⁺ and thiourea precursors. A chemical vapor deposition is used to deposit the i-ZnO from diethyl-Zinc and oxygen precursors and to deposit Al—ZnO from diethyl-Zinc, diethyl-Aluminum, and oxygen precursors.

### BRIEF DESCRIPTION OF THE DRAWINGS

FIGS 1A to 1E schematically illustrate a method for the preparation of a CIGS solar cell on a complexly shaped fabricated object, such as a car body; and

FIGS. 2A to 2G schematically illustrate a method for the preparation of a GIGS solar cell on a complexly shaped object, namely the inside of a glass tube in a superstrate configuration.

### DETAILED DESCRIPTION

In the present application, the following terms are defined as below, unless indicated otherwise.

“Nanoparticles” refers to particles having a size ranging from about 1 nanometer (nm) to 100 micrometer (μ) in at least one dimension.

“Surface-charged” particles refer to nanopartieles having a shield of charges at the interface between the particle surface and the surrounding liquid medium.

“Colloidal suspension” refers to a liquid system wherein surface-charged particles are microscopically suspended due to the electrostatic repel forces between the surface-charged

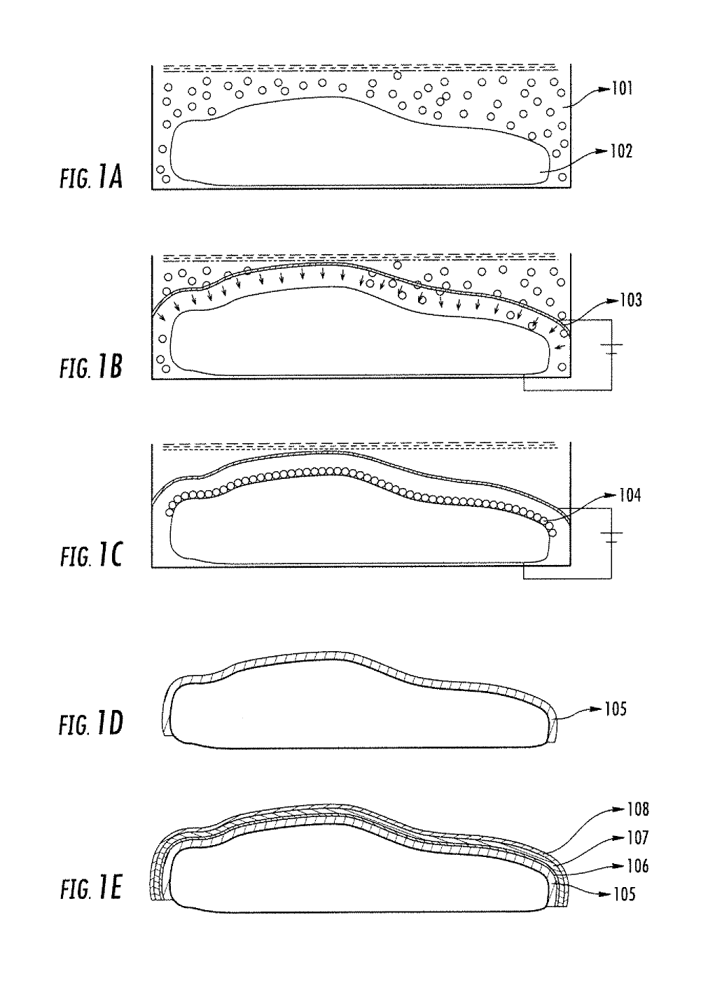

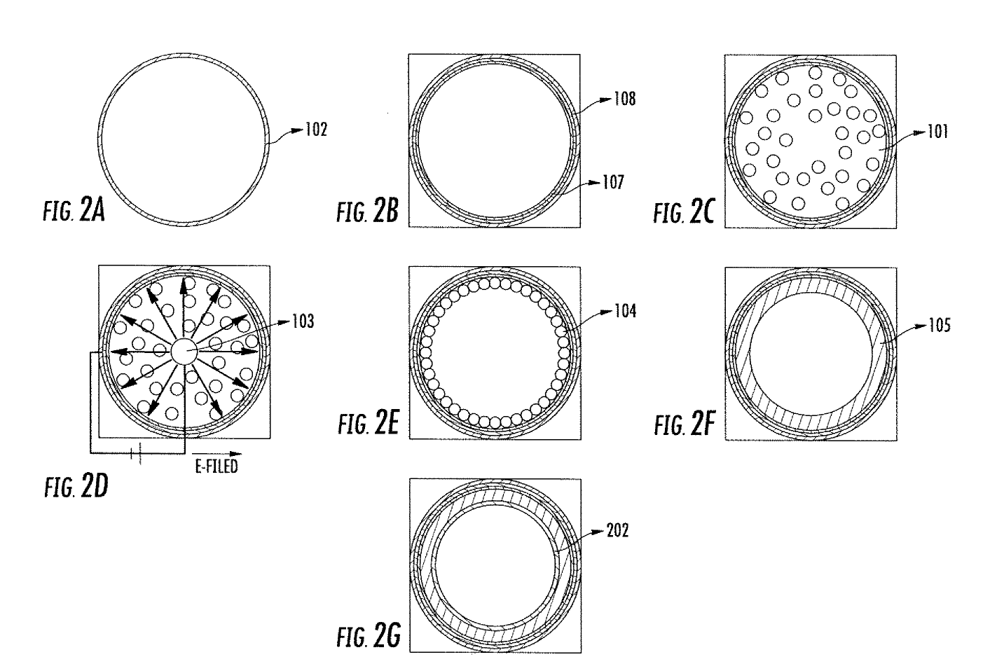

FIGS. 1A to 1E and 2A to 2G illustrate examples for forming CIGS/CZTS layers on complexly shaped surfaces of fabricated objects, which may be greatly different in size and geometry. Corresponding features, appearing in both FIGS. 1 and 2, are designated by the same number. FIGS. 1A to 1E illustrate one implementation of the present invention in which a CIGS/CZTS solar cell is deposited on a car body. FIGS. 2A to 2G illustrate another implementation in which a CIGS/CZTS solar cell is deposited on the inside of a cylinder using a superstrate device configuration

The methods illustrated in FIGS. 1 and 2 provide a low-cost, solution-based technique for growing CIGS or CZTS films on a complexly shaped fabricated objects, for example an object having at least one surface with a curved portion or multiple non-planar surfaces. Such a complexly shaped surface may be characterized as having substantially smooth three-dimensional topography, but in which the topography of the surface may vary substantially, as characterized by the variation in surface height, or by variation in the surface normal along at least a portion of the surface. A surface may comprise one or more planar portions with surface normal oriented along different directions. The surface of the complexly shaped fabricated object may comprise convex and/or concave portions suitably oriented for use in a deposition process.

The examples of FIGS. 1 and 2 illustrate a rather wide range of size variations. Many other possibilities include complex fabricated objects having an outside dimension (e.g.: outer diameter) in a range from millimeters to tens of meters, for example. Thus, in accordance with embodiments and examples described herein, the invention extends fabrication of metal chalcogenide solar cells to three-dimensions, and without a requirement for coplanarity of the substrate surface.

In various embodiments deposition of a CIGS solar cell on a complexly shaped surface according to the present invention includes: generating a nanoparticle colloidal suspension; depositing the suspension via EPD onto the complexly shaped surface to create a metal thin film on the surface; converting the metal thin film into a metal chalcogenide thin film; and using chemical deposition techniques to deposit the CdS and i-ZnO and/or Al—ZnO layers. Parameters for each of these steps are described below.

The nanoparticle colloidal suspension can be generated using many different methods. The choice may be determined by application requirements. One method includes laser ablation of a bulk target material in liquid, in which a high energy laser pulse is directed at a metal target surface. The bulk target material comprises the CIGS or CZTS material of interest. The very short duration laser pulses, on the order of femtosecond to picoseconds, create a plasma which is rapidly cooled by the solvent and forms a nanoparticle colloidal suspension. The laser ablation process maintains the stoichiometry of the metal target in the nanoparticles to within 10%. Another method for formation of nanoparticle colloidal suspensions includes the explosion of thin metal wires, in which metal wires on the order of 1-50 microns may be exploded in solution by applying an increasing DC voltage until they explode. The resulting plasma is rapidly cooled in solution and can form a stable nanoparticle colloidal suspension. Using these methods, a nanoparticle colloidal suspension can be prepared which is largely free of impurities, since no capping agents, or other salts, are necessary to stabilize the particles. A third method, which includes chemical synthesis, can be utilized to form stable nanoparticles by reducing metal salts in the presence of chelating agents such as citrates. These are three methods which could produce an appropriate nanoparticle colloidal suspension for use in the present invention. The nanoparticles may also be prepared as a chemical complex. For example, CIGS nanoparticles may be synthesized through various chemical reaction methods as described in the sonochemical method by J J. Zhu, Chem. Mater. 12, 73, (2000); thermolysis described by M. A. Malik et. al. Adv. Mat. 11, 1441 (1999); and pyrolysis described by S. L. Castro et. al. Chem. Mater. 15, 3142 (2003) such that the resultant nanoparticle contains the desired chemical composition.

Because the nanoparticles may be deposited over large or small areas, which may vary by several orders of magnitude, different techniques for generating the metal nanoparticle colloidal suspension are to be considered. Small quantities of nanoparticles, for example enough to coat several square feet, may be prepared using laser ablation in a liquid. One benefit is the nanoparticles maintain the stoichiometry of the target material. Large quantities of nanoparticles, for example as utilized in a CIGS solar cell deposited on a car body, may be produced by chemical methods or other suitable large scale production methods. The choice may be determined based on area-speed tradeoffs for a particular application.

Referring to FIGS. 1A to 1E and 2A to 2G, the nanoparticle colloidal suspension 101 is composed of metal nanoparticles. Generally, nanoparticle materials suitable for an EPD method include, but are not limited, to metals, alloys, semiconductors, ceramics, glass, polymers, or carbon. For making a CIGS solar cell the particles can comprise Group IB, Group IIIA and optionally, Group VIA elements. The Group IB elements include Cu, Ag and Au with Cu being preferred. The Group IIIA elements include Al, Ga and In with a mixture preferred. The Group VIA elements include Se, S and Te, and these are typically added in the chalcogen conversion phase. Preferably, the nanoparticle colloidal suspension comprises Cu, In, Cu_{X}Ga_{Z}Cu_{X}In_{Y}, or Cu_{X}In_{Y}Ga_{Z}. The atomic ratio of Cu/(In+Ga) is in the range of 0.7-1.0 and the atomic ratio of Ga/(Ga+In) is in the range of 0.1-0.5. The ratio of Cu/(In+Ga) largely determines the carrier concentration of the semiconductor device. If the ratio is less than 0.95, the semiconductor will be an n-type. If the ratio is greater than 0.95, the semiconductor will be a p-type. The ratio of Ga/(Ga+In) can be tuned to modify the bandgap. The bandgaps of CuInSe₂ and CuGaSe₂ are 1.02 eV and 1.65 eV, respectively. The optimal bandgap for a single junction device is about 1.5 eV. Partially replacing In with Ga increases the bandgap, which improves the energy-conversion efficiency and also decreases cost by reducing the amount of In used. The nanoparticle colloidal suspension can be composed of any mixture of Cu, In, Cu_{X}Ga_{Z}, Cu_{X}In_{Y}, and Cu_{X},In_{Y},Ga_{Z} nanoparticles as long as the suspension is stable and the correct ratio of metals is used. Other metal chalcogenide materials, such as CZTS, can also be prepared from suitable metal nanoparticle precursors. In the case of CZTS, the preferred combination includes Group IB elements, Group IIB and/or Group IVA elements and optionally Group VIA elements. The Group IB elements include Cu, Ag and Au with Cu being preferred. The Group IIB elements include Zn, Cd, and Hg with Zn preferred. The Group IVA elements include Si, Ge, Sn and Pb with Si or Sn preferred. The Group VIA elements include Se, S and Te, and these are typically added in the chalcogen conversion phase. Preferably nanoparticle colloidal suspensions of Cu, Zn, Sn, CuₓZn_{y}, CuₓSn_{y}, ZnₓSn_{y}, or CuₓZn_{y}Sn_{z} are used.

The nanoparticles may have a plurality of shapes including but not limited to nanospheres, nanorods, nanowires, nanocubes, nanoflowers, nanoflakes, mixtures of these shapes and the like, depending on the bulk material properties and fabrication method. The desired size of the nanoparticles suitable for the method of the present invention ranges between about 1 nm and 100μ in at least one dimension, preferably between about 1 nm and about 500 nm in at least one dimension. According to an embodiment of this invention, a thin oxide layer may be formed on the surface of the nanoparticle, depending on the particle fabrication method and the liquid medium of the colloidal suspension.

According to an embodiment of the present invention, the nanoparticles are prepared by physical breakdown of bulk source materials, wherein the nanoparticles and the bulk materials have an identical chemical composition. The nanoparticles may be prepared in a preferred liquid medium to form the colloid suspension, or they may be prepared in but not limited to, a vacuum, a gas medium, or a liquid medium, and then re-dispersed in a preferred liquid medium to form the colloid suspension. Methods of preparing the nanoparticles include but are not limited to pulsed laser ablation, laser pyrolysis, arc discharge, thermal evaporation, plasma evaporation, evaporation-condensation, and mechanical ball milling of the bulk material. These methods, indicated as the “physical breakdown methods” suitable for this invention, have an advantage of providing easy controllability of the chemical composition of the nanoparticles by simply adjusting the composition of the source bulk material. In addition, the formation of the bulk material can use a plurality of methods not limited by EPD considerations, and therefore much more complex bulk materials can be prepared. The use of physical breakdown of bulk materials allows the EPD process to have better film quality control, maximizes material usage, and at the same time reduces process complexity.

To deposit the particles onto the substrate 102, electrophoretic deposition (EPD) is utilized in the present invention. In EPD, colloidal surface-charged particles suspended in a liquid medium will migrate under the influence of an external electric field, electrophoresis, and are deposited onto an electrically conductive or semi-conductive surface of the substrate 102, usually charged oppositely to the particles, and referred to as a deposition electrode or substrate 102. All colloidal particles that can be used to form stable suspensions and that can carry a charge can be used in electrophoretic deposition, which makes the process useful for applying materials to any electrically conductive or semi-conductive surface. Under the influence of a strong electric field, the charged particles will move away from a counter electrode 103, which has the same charge as the nanoparticles and toward the oppositely-charged deposition electrode or substrate 102. The flux of particles to the surface can be controlled by varying the DC voltage, solid loading, or the ζ-potential of the particles. Once at the surface, the particles deposit on the surface either by electrochemical reduction of the particle or by sedimentation. In the former case, a positively-charged particle is reduced to the metal at the substrate 102. In the latter case, the moving particles exert a pressure near the surface of the electrode which causes them to sediment onto the surface. In both cases the result is creation of a close-packed metal thin film on the surface of the substrate deposition electrode. According to an embodiment of the present invention, preferably the surface-charged nanoparticles in a stable suspension have an absolute value of zeta potential greater than 10 milliVolts (mV). Zeta potential (ζ) is used to represent the degree of repulsion between adjacent surface-charged nanoparticles. It is determined from the velocity (v) with which the nanoparticle moves under an electric field (E) according to the following equation: ζ=(4πηv)/(εE), where η and ε are the viscosity and dielectric constant of the liquid medium, respectively.

Generally, the substrate 102 on which the absorber layer is deposited is electrically conductive or semi-conductive, and is directly connected to or is the deposition electrode, wherein the deposition surface faces the counter electrode 103. The polarity of the deposition electrode, either positive or negative, is determined as an opposite charge to the charge polarity of the nanoparticles. The substrate 102 also acts as the bottom contact in a photovoltaic device. It may be in the form of, but is not limited to: (1) a rigid sheet of glass with a conductive coating, preferably a metal coating and more preferably a molybdenum coating; (2) a flexible sheet of a metal or an alloy, including but not limited to molybdenum, titanium, stainless steel, or aluminum, with or without additional coatings; or (3) a flexible polymeric sheet having a conductive coating, preferably a metal coating such as molybdenum, tungsten, or chromium and more preferably a molybdenum coating. The suitable polymers for forming the polymeric sheet include, but are not limited to, polyimides, polyethylene terephthalate, or polyethersulphone. In embodiments wherein a metal or an alloy substrate is used, it would be desirable but not necessary to cover the backside of the substrate with a blocking material such as an insulating tape or membrane to inhibit useless deposition on the back side of the substrate. It would also be desirable to pre-coat a thin layer of molybdenum and/or an intermediate blocking layer on the metal sheet to improve adhesion and inhibit interdiffusion between the metal substrate and the deposited film as described in U.S. patent application publication no. 2009/0305455. Obviously, the present method also allows for a portion of a complexly shaped surface to be converted to a solar cell depending on the area that is at least semi-electrically conductive since this is the only portion where the nanoparticles will be deposited by EPD. The counter electrode 103 is typically made of either a conductive metal or a conductive alloy, including but not limited to, stainless steel, molybdenum, nickel, titanium, platinum, gold, or a metal-coated glass sheet.

The voltage applied to the electrodes, the distance between the electrodes, and the current density employed on the electrodes may be configured in light of the intensity of the electric field required for the deposition of the nanoparticles. Depending on the nanoparticle properties and electrode size, the applied voltage may be direct current (DC) or alternating current (AC) and may be either continuous or pulsed. The electrical potential is preferably from 1 to 5000 Volts (V), more preferably from 25 to 5000 V. The distance between the electrodes is preferably from 0.1 to 100 centimeters (cm), more preferably from 0.5 to 10 cm. The current density is preferably from 0.001 to 10 milliAmps/centimeter² (mA/cm²), more preferably from 0.01 to 1 mA/cm². Some embodiments may employ one or more suitable additives to improve the stability and conductivity of the colloidal suspension, or to improve adhesion of the deposited photovoltaic absorber layer at the absorber layer/substrate interface. Such additives include but are not limited to, acids, bases, electrolytes, and surfactants or dispersants which are well known in the colloidal art. However, in various embodiments, such additives should be removable from the absorber layer during or after deposition. Particularly, additives are chosen to ensure that they do not disadvantage the process or the product of the invention.

The deposition speed is determined by the operating parameters. In some embodiments, a 0.5 to 2 micron (μ) thick film with a good packing density may be deposited by the current method in a short time of from 30 seconds to 5 minutes. The deposition speed of the current method is much faster than the conventional vacuum-based techniques, and is among the fastest compared to other non-vacuum-based techniques in terms of depositing a thin film photovoltaic absorber layer with similar packing density.

This technique offers several unique advantages. First, the precursor is fluid, so deposition is conformal, which is unique to our method. Second, the bandgap can be graded by doing multiple depositions with nanoparticles of different compositions. Third, electrophoretic deposition is well established. Electrophoretic deposition has been used to deposit primer layers on car bodies, and the process and composition of the precursor solution is well known in the art. Electrophoretic deposition production lines large enough to accommodate platform trailers have been utilized to apply paint primer coats, which demonstrates the general application of the deposition process for coating large surface areas. According to an embodiment of the present invention, virtually all of the nanoparticles in the liquid medium may be deposited under an optimized configuration of the EPD process onto the substrate. Thus, the material usage is much more efficient in the current method compared to the conventional vacuum-based and other non-vacuum-based techniques. Therefore, the current method helps to reduce the environmental footprint of the process of forming a photovoltaic absorber layer.

To achieve even deposition of the nanoparticle suspension a non-aqueous solvent is used. Moreover, careful consideration of the shape of the counter electrode 103 is needed. In aqueous solutions, water splitting occurs at potentials greater than 1.23 V, and the formation of hydrogen bubbles on the cathode can disrupt the film. In order to avoid these bubbles, non-aqueous solvents are used in the present invention. Non-limiting examples of suitable solvents for the present invention include acetone, organic and non-organic solvents so long as they are non-aqueous. Preferably the solvent comprises single phase polar organic liquids. The polar organic liquid may have a large dielectric constant of more than 10, and more preferably of more than 20. General classes of the polar organic liquids suitable for this invention include but are not limited to, alcohols, ethers, ketones, esters, amides, nitriles, and diols, and the like. Preferably the formula of the polar organic liquid contains 1-6 carbon atoms. Even deposition of the precursor nanoparticle suspension onto the substrate requires that the shape of the counter electrode needs to be designed such that the electric field is uniform over the surface of the substrate. In the case of a highly symmetric object, like a cylinder, deposition on the inside of the object can be accomplished using a rod-shaped counter electrode 103 as shown in FIG. 2D.

In the case of a more complexly shaped object, such as the car body shown in FIGS. 1A to 1E, the shape of the Counter electrode 103 needs to be designed by solving Gauss' Law, as given in EQ1 below:

E=−∇φ (EQ1)

where E is the electric field and φ is the electric potential, with the given substrate surface and under the condition that the electric field is the same at all points between the plates of the deposition electrode 102, as defined by the complex shape, and the counter electrode 103. The geometric shape and the constraint of the electric field determines the shape of the counter electrode 103. Determining the appropriate counter electrode shape can be done using commercially available physics simulation packages such as COSMOL multiphysics modeling and simulation software. The data of the shape of the substrate can be determined using three dimensional laser scanning of the surface, laser stylus contouring, or from CAD/CAM data used to create the substrate surface.

The EPD deposition of the nanoparticles on the surface of the substrate 102 forms a metal thin film 104 which is then converted into a metal chalcogenide thin film 105 by exposing the metal thin film 104 to a chalcogen vapor at an elevated temperature of from 200 to 700° C. for 5 to 60 minutes. The chalcogen vapor can be composed of any of the reactive sulfur or selenium species, such as S₂, Se, H₂S or H₂Se. The sample is placed in sealed container and the reactive gas is either generated in-situ or pumped in. The sample can be heated to facilitate conversion of the metal thin film 104 to a metal chalcogenide thin film 105. In addition, the reaction can be carried out at low pressure by evacuating the reaction vessel or at atmospheric pressure by flowing argon or nitrogen though the cell. Another method for conversion of the metal thin film 104 into a metal chalcogenide thin film 105 is to electrodeposit selenium and/or sulfur and then heat the sample to 200 to 700° C. The deposited selenium and/or sulfur will diffuse into the metal thin film 104 and convert it to a metal chalcogenide thin film 105. Irrespective of how formed, preferably the metal chalcogenide thin film has a thickness of from 100 nm to 10μ.

Chemical deposition techniques can be used to deposit a buffer layer 106, an insulating layer 107, and a transparent conducting oxide layer 108. In this technique, a fluid precursor undergoes a chemical change at a solid surface, leaving a solid layer. Since the fluid precursor surrounds the solid object, deposition happens on every surface, regardless of direction, and thin films from chemical deposition techniques are conformal. Chemical deposition is further categorized by the phase of the precursor. Chemical bath deposition (CBD) uses a liquid precursor, usually a solution of organometallic powders dissolved in an organic solvent. This is a relatively inexpensive, simple thin-film process that is able to produce stoichiometrically accurate crystalline phases. Chemical vapor deposition (CVD) generally uses a gas-phase precursor. In the case of Metal-Organic Chemical Vapor Deposition (MOCVD), an organometallic gas is used. In the present invention, preferably use is made of diethylzinc, water vapor, and diethylaluminum as precursor gasses. The buffer layer may be composed of CdS, Zn(O,S) (zinc oxysulfide), InS, or other related materials which passivate the CIGS surface and/or form a PN junction with the CIGS material to improve carrier collection. The insulating layer may be composed of i-ZnO, i-In₂O₃, or other related materials which form a homojunction with the transparent conducting oxide and prevent shunting in the device. The transparent conducting oxide may be composed of Al—ZnO, F—ZnO, In—SnO, carbon nanotubes, conducting polymers, graphene, or any other suitable transparent conducting material. Chemical deposition is one method currently used to deposit these materials, but other methods which deposit a conformal coating such as EPD or electrodeposition could also be used. In the case of a superstrate cell, such as the one shown in FIGS. 2A to 2G, deposition of the CdS buffer layer 106 may be omitted; however deposition of a back electrode layer 202 is included FIG. 2G.

Some examples of precursor preparation and formation of a metal chalcogenide thin film are discussed in the following paragraphs.

By way of example, a suitable precursor solution was prepared as follows. In this section, all chemicals were used as received. CuIn nanoparticles were prepared by laser ablation of a CuIn 50:50 alloy target from SCI Engineered Materials in acetone, Alfa Aesar, Spectrophotometric grade, 99.5% purity, as the solvent. An IMRA America D-10K fiber laser system was used to produce the particles. The laser output was tuned to 3W and a repetition rate of 500 kHz, 2 μS pulse repetition, was used, yielding pulse energies of 6 μJ. A Scanlab hurrySCAN II system was used to scan the beam across the CuIn target surface. When the beam was focused on the target surface, nanoparticles were produced at a rate of 179 μg/min.

By way of example, the colloidal nanoparticles were deposited on a substrate electrode as follows. Electrophoretic deposition was conducted in a two-electrode cell with the electrodes spaced 2.54 centimeters apart. In the case of a substrate cell, as demonstrated in FIG. 1, a 1 cm² Mo sheet which was 0.010″ thick, Alfa Asear, was used as the cathode deposition electrode, and a stainless steel foil was used as the anode counter electrode, K&S Engineering. The nanoparticles were deposited by applying a bias of 100V between the electrodes using a Keithley 2410 1100V source meter.

By way of example, the metal thin film formed on the Mo sheet was converted to a metal chalcogenide thin film by the following method. The metal thin film was placed in a tube furnace along with a solid piece of Se as the source chalcogen. The container was purged of oxygen by flowing Ar at a rate of 20 cc min⁻¹. Subsequently, the tube furnace was heated to 450° C. for 30 minutes and then the substrate was allowed to cool.

Thus, while only certain embodiments have been specifically described herein, it will be apparent that numerous modifications may be made thereto without departing from the spirit and scope of the invention. It is to be understood that the arrangements are not mutually exclusive, and elements may be combined among embodiments in suitable ways to accomplish desired design objectives. Further, acronyms are used merely to enhance the readability of the specification and claims. It should be noted that these acronyms are not intended to lessen the generality of the terms used and they should not be construed to restrict the scope of the claims to the embodiments described therein.

The foregoing invention has been described in accordance with the relevant legal standards, thus the description is exemplary rather than limiting in nature. Variations and modifications to the disclosed embodiment may become apparent to those skilled in the art and do come within the scope of the invention. Accordingly, the scope of legal protection afforded this invention can only be determined by studying the following claims.

What we claim is:

1. A method for fabricating a conformal metal chalcogenide thin film photovoltaic absorber layer on a surface of a complexly shaped object, the method comprising the steps of:
a.) providing a stable colloidal suspension of metal surface-charged nanoparticles in a non-aqueous solvent, said nanoparticles comprising elements either from Groups IB, IIIA and optionally Group VIA or from Groups IB, IIB and/or IVA and optionally Group VIA;
b.) providing a counter electrode for electrophoretic deposition of said nanoparticles, said counter electrode having a pre-determined shape determined by a surface topography of a surface of a complexly shaped object and providing a substantially constant-electric field constraint between said counter electrode and said surface of said complexly shaped object, said surface being at least semi-electrically conductive;
c.) placing said counter electrode and said surface of said complexly shaped object into said suspension of metal surface-charged nanoparticles and using electrophoretic deposition forming a metal thin film on said surface of said complexly shaped object; and
d.) heating said metal thin film in the presense of a chalcogen to form a metal chalcogenide thin film on said surface of said complexly shaped object.

2. The method of claim 1, wherein said nanoparticles comprise nanoparticles with at least one dimension ranging from 100 microns to 1 nanometer.

3. The method of claim 1, wherein said non-aqueous solvent comprises acetone.

4. The method of claim 1, wherein said nanoparticles comprise Cu, Ga and In and wherein the atomic ratio of Cu:(Ga+In) is from 0.7 to 1.0 and wherein the atomic ratio of Ga:(Ga+In) is from 0.1 to 0.5.

5. The method of claim 1, wherein step c.) comprises the step of applying a voltage bias in the range of 25V to 5000V between said counter electrode and said surface to cause the electrophoretic deposition.

6. The method of claim 1, wherein an additive comprising at least one of an acid, a base, an electrolyte, a surfactant and a dispersant is added to said colloidal suspension to facilitate electrophoretic deposition.

7. The method of claim 1, wherein said surface of said complexly shaped object comprises glass having an electrically conductive coating, a metal, an alloy, or a flexible polymeric sheet coated with molybdenum, tungsten or chromium.

8. The method of claim 1, wherein step d.) comprises forming a metal chalcogenide thin film having a thickness of from 100 nanometers to 10 micrometers.

9. The method of claim 1, wherein step d.) comprises using as said chalcogen any reactive chalcogen of sulfur or selenium.

10. The method of claim 1, wherein step d.) comprises heating the thin metal film to a temperature of from 200 to 700° C.

11. The method of claim 1, wherein step d.) further comprises first depositing said chalcogen onto said metal thin film and then heating said thin film to a temperature of from 200 to 700° C. and causing said chalcogen to diffuse into said thin film.

12. The method of claim 1, comprising the further steps of:
e.) forming a buffer layer adjacent to said metal chalcogenide thin film by a chemical bath deposition;
f.) forming an insulating layer adjacent to a side of said buffer layer opposite said metal chalcogenide thin film layer by a chemical vapor deposition; and
g.) forming a transparent conductive contact adjacent to a side of said insulating layer opposite said buffer layer by a chemical vapor deposition.

13. The method of claim 12, wherein step e.) comprises chemical bath deposition of CdS.

14. The method of claim 12, wherein step f.) comprises chemical vapor deposition of a zinc oxide.

15. The method of claim 12, wherein step g.) comprises chemical vapor deposition of an aluminum doped zinc oxide.

16. The method of claim 10, wherein the heating step is carried out for a period of time of from 5 to 60 minutes.

17. The method of claim 11, wherein the heating step is carried out for a period of time of from 5 to 60 minutes.
